(19) United States
(12) Patent Application Publication
(10) Pub. No.: US 2026/0330767 A1
(43) Pub. Date: Oct. 22, 2026

(54) BIM MODEL LIGHTWEIGHTING METHOD BASED ON FINE-GRAINED GEOMETRIC OBJECT MODELING

(71) Applicants: CCTEG CHONGQING ENGINEERING (GROUP) CO., LTD., Chongqing (CN); CCTEG DIGITAL INNOVATION TECHNOLOGY (CHONGQING) CO., LTD., Chongqing (CN)

(72) Inventors: Xiao MA, Chongqing (CN); Yufei YE, Chongqing (CN); Leixing CHEN, Chongqing (CN); Zepan YANG, Chongqing (CN); Zhixin SUN, Chongqing (CN); Jinyao ZHANG, Chongqing (CN); Cancan LIAO, Chongqing (CN)

(73) Assignees: CCTEG CHONGQING ENGINEERING (GROUP) CO., LTD., Chongqing (CN); CCTEG DIGITAL INNOVATION TECHNOLOGY (CHONGQING) CO., LTD., Chongqing (CN)

(21) Appl. No.: 19/705,016

(22) Filed: Jun. 11, 2026

Related U.S. Application Data
(63) Continuation of application No. PCT/CN2024/129235, filed on Nov. 1, 2024.

(30) Foreign Application Priority Data
Jun. 24, 2024 (CN) 202410820316.9

(51) Int. Cl. G06T 17/20; G06F 30/13

(52) U.S. Cl. CPC G06T 17/205; G06F 30/13; G06T 2210/36

(57) ABSTRACT

Disclosed is a BIM model lightweighting method based on fine-grained geometric object modeling, including the following steps: S1, creating a mapping table T to store data of Face objects and Mesh objects in a model; S2, calling an IExportContext interface in a Revit SDK to extract data of components in the model; S3, checking whether processing of the components in the model has been completed; S4, when the processing has been completed, terminating the process; and when the processing has not yet been completed, acquiring a value of a current flag; S5, when flag=1, calling a Face object lightweighting process and returning to S2; and S6, when flag=0, calling a Mesh object lightweighting process and returning to S2. The present disclosure can effectively simplify model data and achieve model lightweighting. The resulting data supports LOD technology, which can greatly reduce resource consumption during front-end rendering and improve rendering efficiency.

### CROSS-REFERENCE TO RELATED APPLICATIONS

The application claims priority to Chinese patent application No. 202410820316.9, filed on Jun. 4, 2024, the entire contents of which are incorporated herein by reference.

### TECHNICAL FIELD

The present disclosure relates to the technical field of building information modeling (BIM), and in particular to a BIM model lightweighting method based on fine-grained geometric object modeling.

### BACKGROUND

As software designed for building information modeling (BIM), Revit plays an important role in the design, construction, and operation and maintenance phases. In recent years, with the vigorous development of BIM technology, there has been a growing demand across various industries for the use of BIM models in collaborative design, construction management, and operation and maintenance management. Consequently, an important direction in BIM technology development has emerged, that is, how to achieve model lightweighting while ensuring model accuracy, to facilitate viewing in browsers or on mobile phones. In this context, Revit-based BIM lightweighting technology has emerged and has been widely applied and developed.

At present, lightweighting solutions for BIM models employ various techniques, including parametric description, mesh decimation, geometric object instancing, data compression, and the like. However, these techniques all suffer from some limitations. Specifically, although parametric description reduces the file size after lightweighting, it consumes substantial resources on the browser side to recalculate and obtain geometric data of the model. Mesh decimation algorithms consume a significant amount of time during execution, resulting in low operational efficiency. Geometric object instancing can reduce the file size after lightweighting, but different manufacturers often have different requirements for object granularity, and the results after instancing are inconsistent, resulting in poor quality of the lightweight model. Data compression can further process the lightweight files to improve transmission efficiency across networks, but it has no effect on BIM lightweighting itself.

In summary, there is an urgent need for a more reliable and more efficient lightweighting method.

### SUMMARY

An objective of the present disclosure is to provide a BIM model lightweighting method based on fine-grained geometric object modeling, so as to effectively simplify model data and achieve model lightweighting. Moreover, the resulting data supports the level of detail (LOD) technology, which can greatly reduce resource consumption during front-end rendering and improve rendering efficiency.

A basic solution provided by the present disclosure is: a BIM model lightweighting method based on fine-grained geometric object modeling, including the following steps:
S1, creating a mapping table T to store data of Face objects and Mesh objects in a model;
S2, calling an IExportContext interface in a Revit SDK to extract data of components in the model;
S3, checking whether processing of the components in the model has been completed;
S4, when the processing has been completed, terminating the process; and when the processing has not yet been completed, acquiring a value of a current flag;
S5, when flag=1, calling a Face object lightweighting process and returning to S2; and
S6, when flag=0, calling a Mesh object lightweighting process and returning to S2.

Further, the Face object lightweighting process includes the following steps:
S51, calculating a feature vector σ_{Face} of a current Face object according to geometric data provided by the OnPolymesh method;
S52, querying whether the mapping table T contains the feature vector σ_{Face};
S53, when the feature vector is contained, skipping subsequent processing steps and directly terminating the process;
S54, when the feature vector is not contained, determining whether reconstruction is supported;
S55, when reconstruction is not supported, storing the geometric data provided by the OnPolymesh method in the mapping table T; and
S56, when reconstruction is supported, calculating geometric data using a reconstruction method, and storing the resulting geometric data in the mapping table T.

Further, the Mesh object lightweighting process includes the following steps:
S61, calculating a feature vector σ_{Mesh} of a current Mesh object according to geometric data provided by the OnPolymesh method;
S62, querying whether the mapping table T contains the feature vector σ_{Mesh};
S63, when the feature vector is contained, skipping subsequent processing steps and directly terminating the process; and
S64, when the feature vector is not contained, storing the geometric data provided by the OnPolymesh method in the mapping table T.

Further, in the S54, determining whether reconstruction is supported is based on the following conditions:
Condition 1: whether a surface has a single boundary loop; and
Condition 2: the surface is bounded by edges in four directions, where two opposite edges are straight edges, and the remaining two opposite edges are curved edges or edges formed by a plurality of line types; wherein

The surface refers to a surface described by the feature vector σ_{Face}; and when the surface satisfies both Condition 1 and Condition 2, it is determined that reconstruction is supported, otherwise, it is determined that reconstruction is not supported.

Further, in the S56, the reconstruction method includes the following steps:
S561, creating a new vertex array, a triangle mesh vertex index array, a UV array, and a normal vector array;
S562, extracting points along the two opposite curved edges in sequence as vertices, and storing the points into the newly-created vertex array;
S563, calculating UV coordinates of the extracted vertices on the surface, and storing the UV coordinates into the UV array;
S564, calculating normal vector coordinates of the vertices, and storing the normal vector coordinates into the normal vector array;
S565: connecting the vertices on the curved edges in sequence to form polylines approximating the curved edges to obtain two polylines; and
S566, connecting vertices on the two polylines to form a series of polygons, thereby forming a triangle mesh approximating the surface; recording the vertex indices defining the triangle mesh in the triangle mesh vertex index array; where the surface refers to the face represented by the feature vector σ_{Face}, and the curved edges are the edges of the surface.

Further, in the S562, the extraction in sequence is performed according to a left-hand rule.

Further, in the S563, the UV coordinates of the extracted vertices on the surface are calculated using a TessellateOnFace method provided by a Revit Application Programming Interface (API).

Further, in the S564, the normal vector coordinates of the vertices are calculated using a ComputeNormal method provided by the Revit API.

Further, the Face object lightweighting process further includes S57, which employs a point-reduction method to reduce a number of sampled vertices on the curved edges, and then adopts a reconstruction method to generate triangle meshes similar to the surface at varying levels of precision.

Further, the S57 includes the following sub-steps:
S571, predefining an angle ε as a threshold, and calculating a cosine value ω of the angle ε; extracting vertex data of one of the curved edges of the surface, and assuming a vertex set P={p₀, p₁, p₂, p₃, p₄, p₅, . . . }; and setting i=0, a=P[i];
S572, setting j=i+2, b=P[j];
S573, connecting vertices a and b to form a new edge l, and denoting an edge between b and an adjacent point P[j+1] thereof as m;
S574, calculating a cosine value φ of an angle θ between the edge l and the edge m using a dot product formula l·m=|l|*|m|*cos(θ);
S575, when φ is less than ω, marking a vertex pointed to by b for removal, and setting b to a next vertex, that is, j=j+1, b=P[j]; and returning to S573;
S576, when φ is greater than ω, setting a to b, that is, i=j, a=P[i], and returning to S572;
S577, when b points to a last vertex of the curved edge, storing the remaining vertices on the curved edge into the vertex array; and
S578, processing the other curved edge of the surface using the same method; and
S579, recalculating the triangle mesh vertex index array, the UV array, and the normal vector array according to the steps of the reconstruction method.

Working principle and advantages of the present disclosure are as follows:

The present disclosure provides a BIM model lightweighting method based on fine-grained geometric object modeling, which particularly employs finer-grained primitives (corresponding to Face objects and Mesh objects) as a basis, and achieves face-based primitive instantiation during the BIM lightweighting process. Compared with other geometric object instancing methods, the method features finer granularity and a higher rate of geometric reuse. Further, different lightweighting workflows are applied to handle Face objects and Mesh objects, respectively. For the Face objects, the reconstruction method is employed, which can substantially simplify the geometric data associated with regular faces in the Face objects. For other types of surfaces contained in Face objects, as well as for the Mesh objects, an object modeling approach is employed to reduce the volume of data generated after BIM lightweighting, thereby achieving lightweighting of the model data.

In addition, this solution takes into account the application scenarios of the lightweight data on the front end (browser-based environment). Based on the surface reconstruction method, a point-reduction method is further introduced to simplify geometric data and support geometric models at varying levels of precision. Accordingly, the requirements of LOD applications during browser-side rendering of the BIM model are satisfied, significantly reducing resource consumption during front-end rendering and improving rendering efficiency.

### BRIEF DESCRIPTION OF DRAWINGS

FIG. 1 is a schematic diagram of a workflow illustrating a BIM model lightweighting method based on fine-grained geometric object modeling according to Embodiment 1 of the present disclosure.

FIG. 2 is a geometric structural diagram of a Revit model component of a BIM model lightweighting method based on fine-grained geometric object modeling according to Embodiment 1 of the present disclosure.

FIG. 3 is a schematic diagram of a Face object lightweighting process of a BIM model lightweighting method based on fine-grained geometric object modeling according to Embodiment 1 of the present disclosure.

FIG. 4 is a schematic diagram of a Mesh object lightweighting process of a BIM model lightweighting method based on fine-grained geometric object modeling according to Embodiment 1 of the present disclosure.

FIG. 5 is a schematic diagram of a surface reconstruction process of a BIM model lightweighting method based on fine-grained geometric object modeling according to Embodiment 1 of the present disclosure (where two polylines contain an equal number of vertices).

FIG. 6 is a schematic diagram of a surface reconstruction process of a BIM model lightweighting method based on fine-grained geometric object modeling according to Embodiment 1 of the present disclosure (where two polylines contain different numbers of vertices).

FIG. 7 is a geometric structural diagram of a tree model of a BIM model lightweighting method based on fine-grained geometric object modeling according to Embodiment 1 of the present disclosure.

FIG. 8 is a schematic diagram of a point-reduction process of a BIM model lightweighting method based on fine-grained geometric object modeling according to Embodiment 2 of the present disclosure.

FIG. 9 is a schematic diagram of a mesh constructed based on original surface data of a BIM model lightweighting method based on fine-grained geometric object modeling according to Embodiment 2 of the present disclosure.

FIG. 10 is a schematic diagram of a mesh constructed using a surface reconstruction method of a BIM model lightweighting method based on fine-grained geometric object modeling according to Embodiment 2 of the present disclosure.

FIG. 11 is a schematic diagram of a medium-precision mesh constructed using a point-reduction method of a BIM model lightweighting method based on fine-grained geometric object modeling according to Embodiment 2 of the present disclosure.

FIG. 12 is a schematic diagram of a coarse mesh constructed using a point-reduction method of a BIM model lightweighting method based on fine-grained geometric object modeling according to Embodiment 2 of the present disclosure.

### DETAILED DESCRIPTION OF THE EMBODIMENTS

The present disclosure will be further described in detail below by means of specific embodiments:

### Embodiment 1

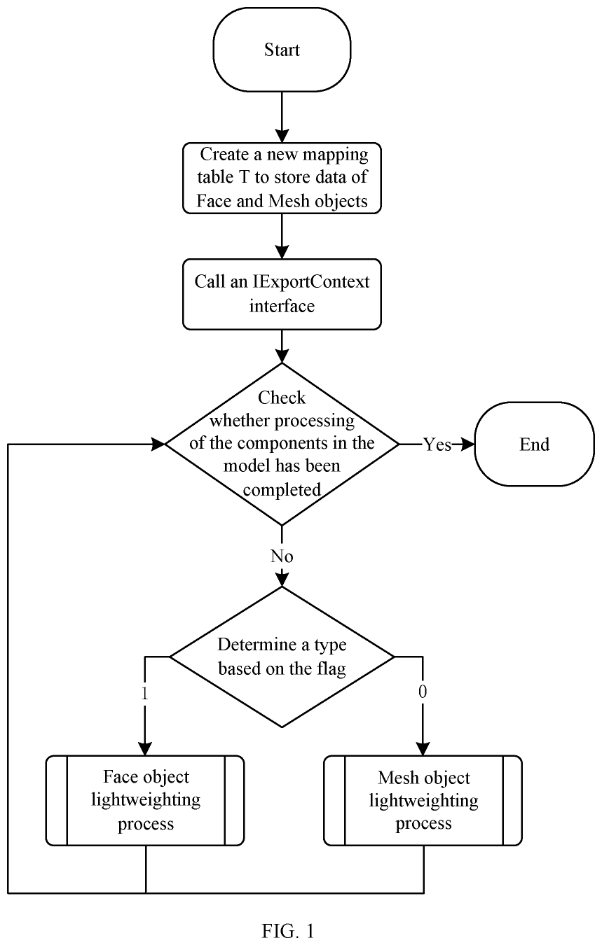

As shown in FIG. 1, this embodiment provides a BIM model lightweighting method based on fine-grained geometric object modeling, including the following steps:
S1, creating a mapping table T to store data of Face objects and Mesh objects in a model.

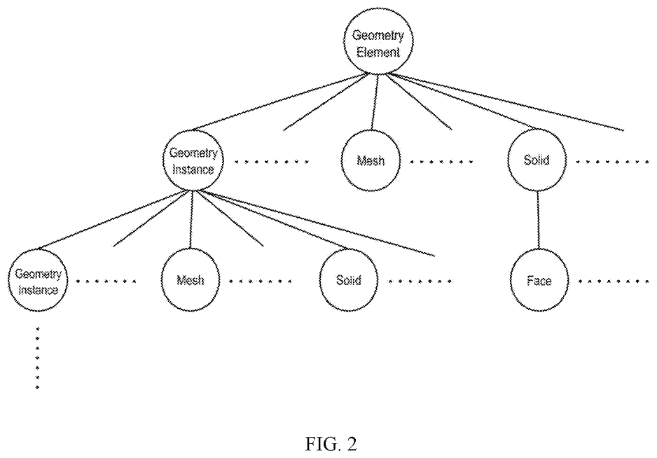

The model refers to a BIM model based on Revit software, that is, a Revit model; and the method described herein is primarily designed for execution within a Revit software environment. Specifically, Face objects and Mesh objects exist as fundamental primitives in the Revit model. As shown in FIG. 2, in Revit software, a geometric structure of model components is organized in a tree-like hierarchy. A root thereof is a Geometry Element object, which, serving as a collection, includes a plurality of Solid, Geometry Instance, and Mesh objects, and the Geometry Instance object is itself a collection, which likewise includes a plurality of Solid, Geometry Instance, and Mesh objects, and the Solid object includes a plurality of Face objects. That is, the Revit model includes two types of surface representations: Mesh and Face. The Face entity further encompasses various regular face types, including planar face, conical face, cylindrical face, and other regular face types.

This solution selects Face objects and Mesh objects as targets for data processing, with finer object granularity, and enables comprehensive processing of the model objects.
S2, calling an IExportContext interface in a Revit SDK to extract data of components in the model.

Specifically, the Revit SDK refers to an Autodesk Revit Software Development Kit, which is a software development framework that enables developers to extend and customize functions of Revit, and create plug-ins or custom applications to meet specific design, construction, or project management requirements. The Revit SDK provides an application programming interface (API), that is, a set of predefined interfaces and classes, through which the developers can access the core functions of Revit, such as model data, command execution, and user interface operations. The IExportContext interface is used to export (extract) model data.
S3, checking whether processing of the components in the model has been completed. Specifically, when the IExportContext interface calls a Finish method, it indicates that all components in a current scene have been fully processed.
S4, when the processing has been completed, terminating the process; and when the processing has not yet been completed, acquiring a value of a current flag.

Specifically, in this embodiment, a flag switch flag is established, with an initial value of 0. When an OnFaceBegin method of the IExportContext interface is called, a value of flag is set to 1; when an OnFaceEnd method is called, a value of the flag is reset to 0. When the program calls an OnPolymesh method, the value of the flag is checked: when the value of the flag is 0, it indicates that Mesh object data is currently being processed; when the value of the flag is 1, it indicates that Face object data is currently being processed.
S5, when flag=1, calling a Face object lightweighting process and returning to S2.

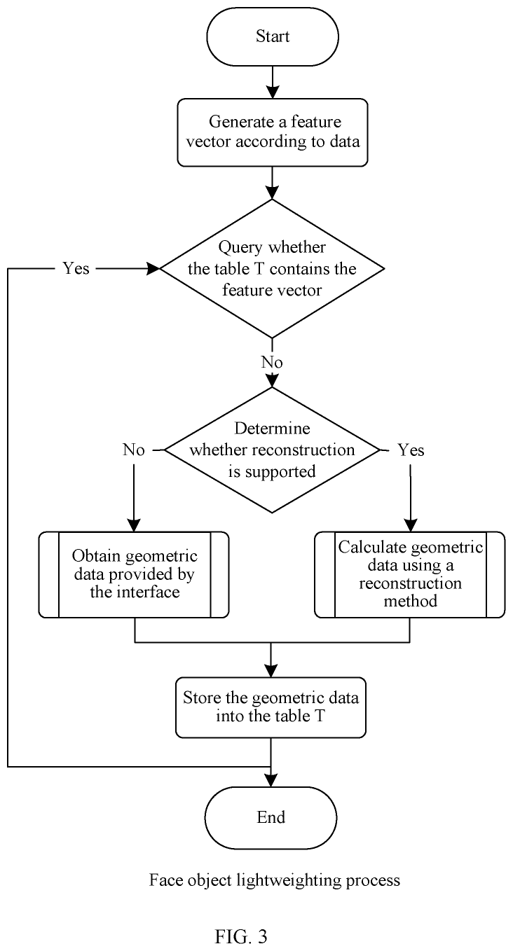

As shown in FIG. 3, the Face object lightweighting process includes the following steps:
S51, calculating a feature vector σ_{Face} of a current Face object according to geometric data provided by the OnPolymesh method.

Specifically, the geometric data associated with different Face objects or Mesh objects is inconsistent. Based on these differences in data, corresponding feature vectors may be constructed, thereby enabling rapid differentiation of different geometric objects through the feature vectors. For the current Face object, a feature vector is established based on data, such as vertices, triangle mesh indices, UV coordinates, and normal vectors provided by the OnPolymesh method. For example, the following feature vector may be established using data, such as a number of vertices np, a number of triangle mesh indices ni, a number of UVs nuv, a number of normal vectors nf, and a small number of vertices P and their corresponding normal vectors N and UV coordinates: [np, ni, nuv, nf, P[0]ₓ, P[0]_{y}, P[0]_{z}, N[0]ₓ, N[0]_{y}, N[0]_{z}, UV[0]_{U}, UV[0]ᵥ, . . . ].
S52, querying whether the mapping table T contains the feature vector σ_{Face}.
S53, when the feature vector is contained, skipping subsequent processing steps and directly terminating the process.
S54, when the feature vector is not contained, determining whether reconstruction is supported.

In this step, determining whether reconstruction is supported is based on the following conditions:
Condition 1: whether the surface has a single boundary loop, that is, the surface contains no holes; and
Condition 2: the surface is bounded by edges in four directions, where two opposite edges are straight edges, and the remaining two opposite edges are curved edges or edges formed by a plurality of line types.

The surface refers to a surface described by the feature vector σ_{Face}; and when the surface satisfies both Condition 1 and Condition 2, it is determined that reconstruction is supported, otherwise, it is determined that reconstruction is not supported.
S55, when reconstruction is not supported, storing the geometric data provided by the OnPolymesh method in the mapping table T.
S56, when reconstruction is supported, calculating geometric data using a reconstruction method, and storing the resulting geometric data in the mapping table T.

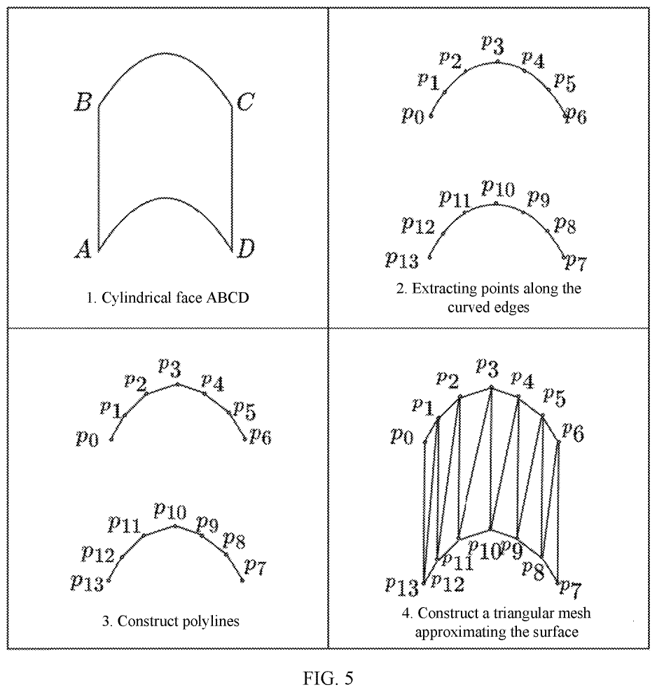

Specifically, as shown in FIG. 5, the reconstruction method includes the following steps:
S561, creating a new vertex array, a triangle mesh vertex index array, a UV array, and a normal vector array.
S562, extracting points along the two opposite curved edges in sequence as vertices, and storing the points into the newly-created vertex array.

Specifically, since Revit employs a left-handed coordinate system, the extraction in sequence is performed according to a left-hand rule.
S563, calculating UV coordinates of the extracted vertices on the surface, and storing the UV coordinates into the UV array.

Specifically, the UV coordinates of the extracted vertices on the surface are calculated using a TessellateOnFace method provided by the Revit API.
S564, calculating normal vector coordinates of the vertices, and storing the normal vector coordinates into the normal vector array.

Specifically, the normal vector coordinates of the vertices are calculated using a ComputeNormal method provided by the Revit API.
S565: Connecting the vertices on the curved edges in sequence to form polylines approximating the curved edges to obtain two polylines.
S566, connecting vertices on the two polylines to form a series of polygons, thereby forming a triangle mesh approximating the surface.

As shown in FIG. 5, when a number of vertices on the two polylines is equal, corresponding vertices on the two polylines are connected to form a series of quadrilaterals, and a diagonal line of each quadrilateral is then connected to form a triangle mesh approximating the surface.

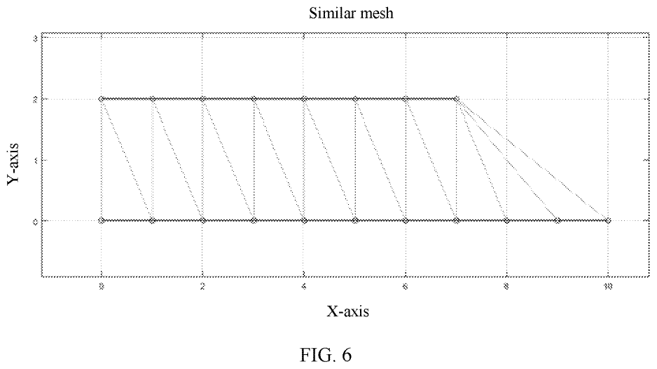

When a number of vertices on the two polylines is not equal, corresponding vertices on the two polylines are connected to form a series of quadrilaterals, a diagonal line of each quadrilateral is then connected, and excess vertices on the longer polyline (the one with the greater number of vertices) are connected to a last vertex on the other polyline to form a triangle, thereby forming a triangle mesh approximating the surface, as shown in FIG. 6.

The vertex indices defining the triangle mesh are stored in the triangle mesh vertex index array. The surface refers to the face represented by the feature vector σ_{Face}, and the curved edges are the edges of the surface.

Based on the reconstruction method, these regular faces in the Face objects may be approximately described with fewer vertices, thereby achieving data simplification of the Face objects. In addition, for Face objects that cannot be reconstructed and Mesh objects, a data volume after BIM lightweighting is reduced through an object modeling approach (corresponding to S55 and the Mesh object lightweighting processing process), achieving improved lightweighting performance.
S6, when flag=0, calling a Mesh object lightweighting process and returning to S2.

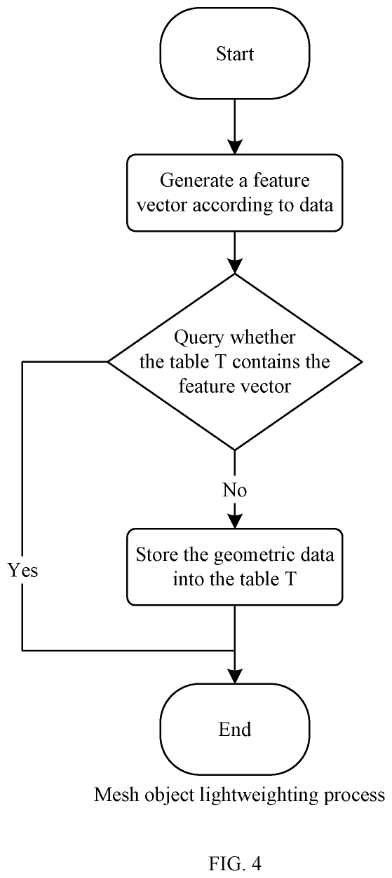

As shown in FIG. 4, the Mesh object lightweighting process includes the following steps:
S61, calculating a feature vector σ_{Mesh} of a current Mesh object according to geometric data provided by the OnPolymesh method.
S62, querying whether the mapping table T contains the feature vector σ_{Mesh}.
S63, when the feature vector is contained, skipping subsequent processing steps and directly terminating the process.
S64, when the feature vector is not contained, storing the geometric data provided by the OnPolymesh method in the mapping table T.

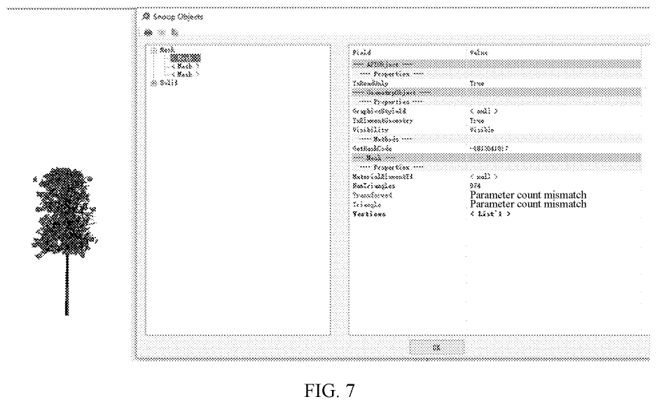

For ease of understanding, the Mesh object lightweighting processing process is described below in conjunction with a tree model example shown in FIG. 7:
step 1, creating a mapping table T in advance, and initializing a flag to 0;
step 2, calling an IExportContext interface in a Revit SDK to extract data of components in the model;
step 3, checking the value of the flag when executing the OnPolymesh method;
step 4, when flag=0, indicating that data of Mesh objects is currently being extracted, calculating a feature vector σ_{Mesh} of the Mesh objects according to a vertex array and a triangle mesh vertex index array provided by the OnPolymesh method;
step 5, querying whether the mapping table T contains the feature vector σ_{Mesh};
step 6, when the feature vector is contained, terminating the process; and
step 7, when the feature vector is not contained, storing data such as a vertex array, a triangle mesh vertex index array, a UV array, and a normal vector array provided by the OnPolymesh method in the mapping table T using the feature vector σ_{Mesh} as a key.

The BIM model lightweighting method based on fine-grained geometric object modeling provided in this embodiment is based on finer-grained primitives, and achieves face-based primitive instantiation during the BIM lightweighting process. Compared with other geometric object instancing methods, the method features finer granularity and a higher rate of geometric reuse. On this basis, a geometric reconstruction method is further provided, the method significantly simplifies the geometric data of regular faces, resulting in a smaller data volume and enabling further lightweighting of the model data.

### Embodiment 2

This embodiment provides a BIM model lightweighting method based on fine-grained geometric object modeling. On the basis of Embodiment 1, the Face object lightweighting process further includes S57, which employs a point-reduction method to reduce a number of sampled vertices on the curved edges, and then adopts a reconstruction method to generate triangle meshes similar to the surface at varying levels of precision.

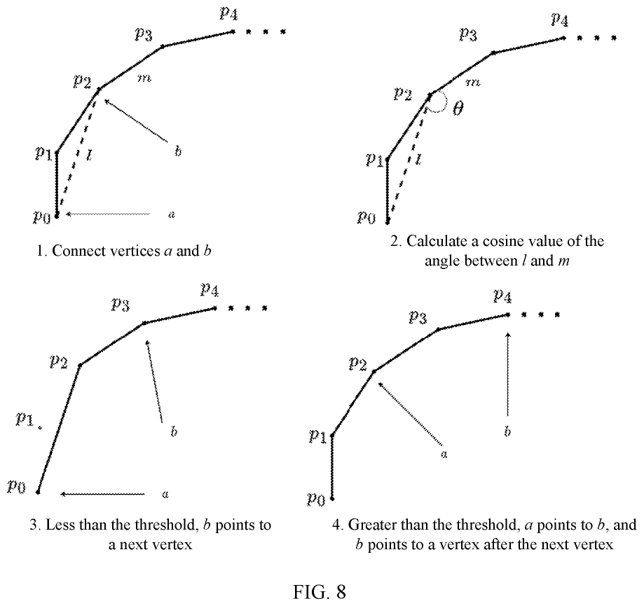

As shown in FIG. 8, the S57 includes the following sub-steps:
S571, predefining an angle ε as a threshold, and calculating a cosine value ω of the angle ε; extracting vertex data of one of the curved edges of the surface, and assuming a vertex set P={p₀, p₁, p₂, p₃, p₄, p₅, . . . }; and setting i=0, a=P[i];
S572, setting j=i+2, b=P[j];
S573, connecting vertices a and b to form a new edge l, and denoting an edge between b and an adjacent point P[j+1] thereof as m;
S574, calculating a cosine value φ of an angle θ between the edge l and the edge m using a dot product formula l·m=|l|*|m|*cos(θ);
S575, when φ is less than ω, marking a vertex pointed to by b for removal, and setting b t a next vertex, that is, j=j+1, b=P[j], and returning to S573;
S576, when φ is greater than ω, setting a to b, that is, i=j, a=P[i], and returning to S572;
S577, when b points to a last vertex of the curved edge, storing the remaining vertices on the curved edge into the vertex array; and
S578, processing the other curved edge of the surface using the same method. The point-reduction method corresponds to the steps S571-S578.
S579, recalculating the triangle mesh vertex index array, the UV array, and the normal vector array according to the steps of the reconstruction method.

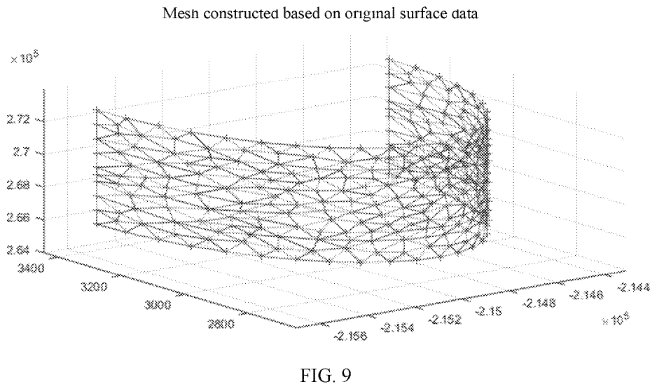

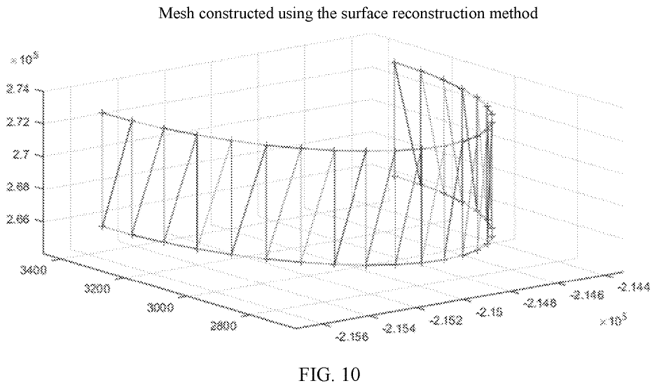

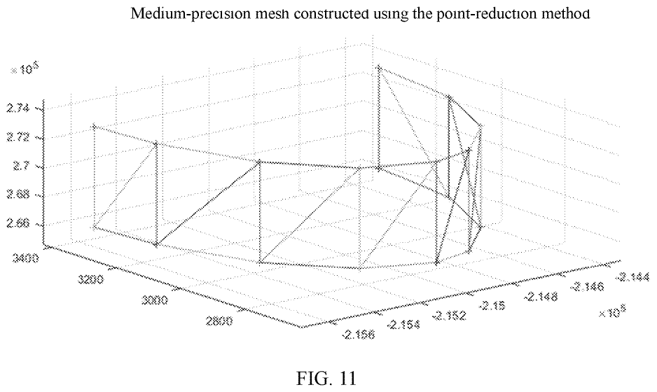

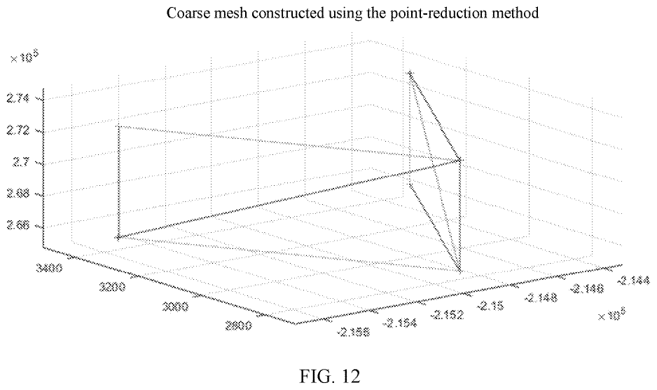

For ease of understanding, the cylinder face most commonly used in an electromechanical model is taken as an example, an overall reconstruction process of the cylindrical face is described below, including the following steps:
step 1, creating a mapping table T in advance, and initializing a flag to 0;
step 2, calling an IExportContext interface in a Revit SDK to extract data of components in the model;
step 3, setting a value of the flag to 1 when an OnFaceBegin method of the IExportContext interface is called;
step 4, checking the value of the flag when executing the OnPolymesh method;
step 5, when flag=1, indicating that data of Face objects is currently being extracted, calculating a feature vector σ_{Face} of the Face objects according to a vertex array and a triangle mesh vertex index array provided by the OnPolymesh method;
step 6, querying whether the mapping table T contains the feature vector σ_{Face};
step 7, when the feature vector is contained, skipping to step 12;
step 8, when the feature vector is not contained, determining whether the cylindrical face satisfies the reconstruction conditions according to the composition and type of edges of the cylindrical face, that is, determining whether reconstruction is supported;
step 9, when the reconstruction conditions are satisfied (that is, reconstruction is supported), extracting a vertex array of the curved edge according to the reconstruction steps, and calculating data such as a triangle mesh vertex index array, a UV array, and a normal vector array, and recording the data in the mapping table T;
step 10, calculating geometric data of the cylindrical face at varying levels of precision according to the new vertex array, the triangle mesh vertex index array, the UV array, and the normal vector array, and generating corresponding vertex arrays, triangle mesh vertex index arrays, UV arrays, and normal vector arrays under the varying levels of precision, and updating the data in the mapping table T. The reconstructed results are shown in FIGS. 9, 10, 11, and 12;
step 11, when the reconstruction conditions are not satisfied (that is, reconstruction is not supported), recording the data provided by the OnPolymesh method in the mapping table T; and
step 12, setting a value of the flag to 0 when an OnFaceEnd method of the IExportContext interface is called.

On the basis of Embodiment 1, the BIM model lightweighting method based on fine-grained geometric object modeling provided in this embodiment additionally introduces a point-reduction method, which can further simplify geometric data to support geometric models at varying levels of precision. Furthermore, since the level of detail (LOD) technology is commonly used during browser-side rendering of the BIM model to reduce browser resource consumption and improve rendering efficiency, it is necessary for surfaces to provide data at varying levels of precision, such as fine, medium, and coarse. This solution can meet the above requirements and provide support for LOD technology during the front-end rendering, significantly reducing resource consumption during front-end rendering and improving rendering efficiency.

The foregoing description is merely embodiments of the present disclosure. General knowledge such as structures and characteristics well known in the solution are not excessively described herein. Those of ordinary skill in the art are deemed to possess all general technical knowledge in the technical field of the present disclosure before the filing date or priority date, and to be capable of accessing all prior art in the field and applying conventional experimental means prior to that date. In the light of the teaching disclosed by the present disclosure, those of ordinary skill in the art can complete and implement the solution in combination with their own abilities. Some typical and publicly known structures or methods shall not become obstacles to those skilled in the art in implementing the present disclosure. It should be noted that various modifications and improvements may be made by those skilled in the art without departing from the scope and spirit of the present disclosure, and these transformations and improvements shall fall within the scope of protection of the present disclosure, and may not affect the implementation effect of the present disclosure and the practicality of the patent.

What is claimed is:

1. A BIM model lightweighting method based on fine-grained geometric object modeling, comprising the following steps:
S1, creating a mapping table T to store data of Face objects and Mesh objects in a model;
S2, calling an IExportContext interface in a Revit SDK to extract data of components in the model;
S3, checking whether processing of the components in the model has been completed;
S4, when the processing has been completed, terminating the process; and when the processing has not yet been completed, acquiring a value of a current flag;
S5, when flag=1, calling a Face object lightweighting process and returning to S2; and
S6, when flag=0, calling a Mesh object lightweighting process and returning to S2.

2. The BIM model lightweighting method based on fine-grained geometric object modeling according to claim 1, wherein the Face object lightweighting process comprises the following steps:
S51, calculating a feature vector σ_{Face} of a current Face object according to geometric data provided by an OnPolymesh method;
S52, querying whether the mapping table T contains the feature vector σ_{Face};
S53, when the feature vector is contained, skipping subsequent processing steps and directly terminating the process;
S54, when the feature vector is not contained, determining whether reconstruction is supported;
S55, when reconstruction is not supported, storing the geometric data provided by the OnPolymesh method in the mapping table T; and
S56, when reconstruction is supported, calculating geometric data using a reconstruction method, and storing the resulting geometric data in the mapping table T.

3. The BIM model lightweighting method based on fine-grained geometric object modeling according to claim 1, wherein the Mesh object lightweighting process comprises the following steps:
S61, calculating a feature vector σ_{Mesh} of a current Mesh object according to geometric data provided by the OnPolymesh method;
S62, querying whether the mapping table T contains the feature vector σ_{Mesh};
S63, when the feature vector is contained, skipping subsequent processing steps and directly terminating the process; and
S64, when the feature vector is not contained, storing the geometric data provided by the OnPolymesh method in the mapping table T.

4. The BIM model lightweighting method based on fine-grained geometric object modeling according to claim 2, wherein in the S54, determining whether reconstruction is supported is based on the following conditions:
Condition 1: whether a surface has a single boundary loop; and
Condition 2: the surface is bounded by edges in four directions, wherein two opposite edges are straight edges, and the remaining two opposite edges are curved edges or edges formed by a plurality of line types; and
the surface refers to a surface described by the feature vector σ_{Face}; and when the surface satisfies both Condition 1 and Condition 2, it is determined that reconstruction is supported, otherwise, it is determined that reconstruction is not supported.

5. The BIM model lightweighting method based on fine-grained geometric object modeling according to claim 2, wherein in the S56, the reconstruction method comprises the following steps:
S561, creating a new vertex array, a triangle mesh vertex index array, a UV array, and a normal vector array;
S562, extracting points along the two opposite curved edges in sequence as vertices, and storing the points into the newly-created vertex array;
S563, calculating UV coordinates of the extracted vertices on the surface, and storing the UV coordinates into the UV array;
S564, calculating normal vector coordinates of the vertices, and storing the normal vector coordinates into the normal vector array;
S565, connecting the vertices on the curved edges in sequence to form polylines approximating the curved edges to obtain two polylines; and
S566, connecting vertices on the two polylines to form a series of polygons, thereby forming a triangle mesh approximating the surface; and
storing vertex indices defining the triangle mesh in the triangle mesh vertex index array; wherein the surface refers to a surface described by the feature vector σ_{Face}, and the curved edges are the edges of the surface.

6. The BIM model lightweighting method based on fine-grained geometric object modeling according to claim 5, wherein in the S562, the extraction in sequence is performed according to a left-hand rule.

7. The BIM model lightweighting method based on fine-grained geometric object modeling according to claim 5, wherein in the S563, the UV coordinates of the extracted vertices on the surface are calculated using a TessellateOnFace method provided by a Revit Application Programming Interface (API).

8. The BIM model lightweighting method based on fine-grained geometric object modeling according to claim 5, wherein in the S564, the normal vector coordinates of the vertices are calculated using a ComputeNormal method provided by the Revit API.

9. The BIM model lightweighting method based on fine-grained geometric object modeling according to claim 2, wherein the Face object lightweighting process further comprises S57, which reduces a number of sampled vertices on the curved edges using a point-reduction method, and generates triangle meshes similar to the surface at varying levels of precision using the reconstruction method.

10. The BIM model lightweighting method based on fine-grained geometric object modeling according to claim 9, wherein the S57 comprises the following sub-steps:
S571, predefining an angle ε as a threshold, and calculating a cosine value ω of the angle ε; extracting vertex data of one of the curved edges of the surface, and assuming a vertex set P={p₀, p₁, p₂, p₃, p₄, p₅, . . . }; and setting i=0, a=P[i];
S572, setting j=i+2, b=P[j];
S573, connecting vertices a and b to form a new edge l, and denoting an edge between b and an adjacent point P[j+1] thereof as m;
S574, calculating a cosine value φ of an angle θ between the edge l and the edge m using a dot product formula l·m=|l|*|m|*cos(θ);
S575, when φ is less than ω, marking a vertex pointed to by b for removal, and setting b to a next vertex, that is, j=j+1, b=P[j]; and returning to S573;
S576, when φ is greater than ω, setting a to b, that is, i=j, a=P[i]; and returning to S572;
S577, when b points to a last vertex of the curved edge, storing the remaining vertices on the curved edge into the vertex array; and
S578, processing the other curved edge of the surface using the same method; and
S579, recalculating the triangle mesh vertex index array, the UV array, and the normal vector array according to the steps of the reconstruction method.
